(19) United States
(12) Patent Application Publication
(10) Pub. No.: US 2025/0226128 A1
(43) Pub. Date: Jul. 10, 2025

(54) BUS STRUCTURE SYSTEMS AND METHODS

(71) Applicant: Avery Dennison Retail Information Services LLC, Mentor, OH (US)

(72) Inventor: Ian J. FORSTER, Chelmsford (GB)

(21) Appl. No.: 18/727,803

(22) PCT Filed: Feb. 15, 2023
(86) PCT No.: PCT/IB2023/051381

§ 371 Date: Jul. 10, 2024

Related U.S. Application Data
(60) Provisional application No. 63/268,101, filed on Feb. 16, 2022.

(51) Int. Cl. H01B 5/14

(52) U.S. Cl. CPC H01B 5/14

(57) ABSTRACT

A system and method for attaching devices with straps to a common bus includes a bus having a flexible non-conductive substrate configured for roll-to-roll processing and two or more flexible bus conductors disposed on the substrate. The flexible bus conductors are configured to receive devices with straps via roll-to-roll processing. Each device with straps is capacitively coupled to at least two of the bus conductors using pressure sensitive adhesive. The flexible bus conductors are configured to transfer power, data, or power and date with each attached device with straps. Each device with straps can be an energy harvester device, an energy storage device, an energy consuming device, a sensor device, or a control device.

### CROSS-REFERENCE TO RELATED APPLICATION(S)

The present application claims the benefit of U.S. Provisional Patent Application No. 63/268,101 filed Feb. 16, 2022, the entirety of which is incorporated herein by reference.

### TECHNICAL FIELD

The present disclosure relates to bus structures for attaching devices and, more specifically, to a flexible bus structure for device attachment using strap attach based roll-to-roll technology and methods of making and using flexible bus structures.

### BACKGROUND

Busses are a group of related electrical wires or conductors that allow multiple devices to share common power lines or data communication links. Power busses can include one or more power rails, which may have the same or different voltages or power phases. A power bus often includes a neutral or return line. Data communication busses can be parallel or serial, and can include separate data, addressing, and control lines.

### SUMMARY

Bus structures for attaching devices and, more specifically, for attaching devices to a flexible bus structure for device attachment using strap attach based roll-to-roll technology and methods of making and using thereof are described herein. In some aspects of the invention, the bus includes a plurality of bus conductors disposed on, or attached or adhered to, a flexible non-conductive substrate. In some aspects of the invention, the bus (including bus conductors) and substrate is configured for roll-to-roll processing. In some aspects of the invention, two or more devices are coupled to at least two data conductors via straps associated with each of the devices. In some aspects of the invention, the bus conductors are configured to receive the devices and transfer power, data signals, or power and data signals with the attached devices.

In some aspects of the invention, a bus for roll-to-roll processing includes a plurality of flexible bus conductors disposed on, or attached or adhered to, a flexible non-conductive substrate and configured to transfer power and/or data. In some aspects of the invention, the bus is configured to transfer power and data. In some aspects of the invention, the bus conductors are further configured to receive devices having straps that are configured to be capacitively coupled to two or more of the bus conductors using one or more pressure sensitive adhesives.

Method of making bus structures for attaching devices and, more specifically, to a flexible bus structure for device attachment using strap attach based roll-to-roll technology and methods of making and using thereof are also described herein. In some aspects of the invention, the method includes receiving a roll that includes a plurality of flexible bus conductors disposed on, or attached or adhered to, a flexible non-conductive substrate that are configured to receive devices with straps and that are configured to transfer power, data, or power and data with the devices with straps. In some aspects of the invention, the method further includes attaching each of the devices to two or more of the bus conductors in a roll-to-roll processing device using a pressure sensitive adhesive that capacitively couples the devices with straps to the bus conductors.

In some aspects, the techniques described herein relate to a bus, including: a substrate that is flexible non-conductive and configured for roll-to-roll processing; a plurality of bus conductors disposed on the substrate and configured to: receive at least one device, and transfer one or more of power or data signals to the at least one device; and at least one strap configured to couple a respective bus conductor of the plurality of bus conductors to a respective contact of the at least one device.

In some aspects, the techniques described herein relate to a bus, wherein the at least one device is an energy harvester device selected from the group consisting of: a photovoltaic cell, a radio frequency energy harvester, and a mechanical energy harvester.

In some aspects, the techniques described herein relate to a bus, wherein the at least one device is an energy storage device that includes one or more of: a battery, a rechargeable battery, a capacitor, or a supercapacitor.

In some aspects, the techniques described herein relate to a bus, wherein the at least one device is an energy consuming device selected from the group consisting of: an emissive display, a reflective display, an acoustic emitter, and a radio signal device.

In some aspects, the techniques described herein relate to a bus, wherein the at least one device is a sensor device selected from the group consisting of: a temperature sensor, an acoustic energy sensor, an accelerometer, a shock sensor, a gas sensor, a smoke sensor, a carbon monoxide sensor, a water sensor, a PH sensor, a Hall effect sensor, and a chemical sensor.

In some aspects, the techniques described herein relate to a bus, wherein the at least one device is a control device that includes one or more of: a processor, a programmable logic device, or a microcontroller.

In some aspects, the techniques described herein relate to a bus, wherein the substrate includes a material selected from the group consisting of plastic, polyethylene terephthalate, treated paper, and coated paper.

In some aspects, the techniques described herein relate to a bus, wherein each conductor is selected from the group consisting of a conductive ink printed onto the substrate, a metal foil secured on the substrate, an aluminum metal foil secured on the substrate, a copper clad metal foil secured on the substrate, a die cut metal foil secured on the substrate, a laser etched metal foil secured on the substrate, and a metal vacuum deposited onto the substrate.

In some aspects, the techniques described herein relate to a bus, wherein the substrate and the plurality of bus conductors are configured to be stored in a roll without devices and receive a plurality of the at least one device that are attached to two or more of the plurality of bus conductors via roll-to-roll processing.

In some aspects, the techniques described herein relate to a bus, wherein the plurality of bus conductors include exactly two bus conductors configured to conduct both power and data signals.

In some aspects, the techniques described herein relate to a bus, wherein the plurality of bus conductors includes at least one bus conductor configured to conduct only power and at least one bus conductor configured to conduct only data signals.

In some aspects, the techniques described herein relate to a bus, wherein the at least one device is conductively coupled to at least two bus conductors of the plurality of bus conductors.

In some aspects, the techniques described herein relate to a bus, wherein the at least one device is capacitively coupled to at least two bus conductors of the plurality of bus conductors via a pressure sensitive adhesive.

In some aspects, the techniques described herein relate to a bus, wherein the at least one device is inductively or capacitively coupled to at least two bus conductors of the plurality of bus conductors.

In some aspects, the techniques described herein relate to a bus, wherein the at least one device includes a rectifier circuit configured to convert an alternating current signal from one or more of the plurality of bus conductors into direct current.

In some aspects, the techniques described herein relate to a bus, wherein the at least one device includes a detector circuit configured to demodulate data from a data signal received from one or more of the plurality of bus conductors.

In some aspects, the techniques described herein relate to a bus, wherein the at least one device includes an oscillator circuit configured to modulate data or power that is coupled onto one or more of the plurality of bus conductors.

In some aspects, the techniques described herein relate to a bus for roll-to-roll processing, including: a flexible non-conductive substrate configured for roll-to-roll processing; and a plurality of flexible bus conductors disposed on the substrate, configured to: transfer one or more of power or data signals, and receive a plurality of devices with straps that are configured to be capacitively coupled to at least two bus conductors using a pressure sensitive adhesive.

In some aspects, the techniques described herein relate to a bus for roll-to-roll processing, further including: a plurality of devices with straps, each device attached to respective bus conductors with pressure sensitive adhesive via roll-to-roll processing, and each selected from the group consisting of an energy harvester device, an energy storage device, an energy consuming device, a sensor device, and a control device.

In some aspects, the techniques described herein relate to a method, including: receiving, in a roll-to-roll processing device, a roll of flexible non-conductive substrate that includes, disposed on the substrate, a plurality of flexible bus conductors configured to receive a plurality of devices with straps and transfer one or more of power or data signals between the plurality of devices; and attaching, in a roll to roll processing device and using a pressure sensitive adhesive, each of the plurality of devices with straps to at least two of the plurality of flexible bus conductors, wherein the pressure sensitive adhesive capacitively couples each device to the at least two of the plurality of flexible bus conductors.

### BRIEF DESCRIPTION OF THE DRAWINGS

Various aspects of the invention will become better understood with regard to the following description, appended claims, and accompanying drawings.

FIG. 1 depicts a block diagram of a bus structure for strap attach devices.

FIG. 2 depicts a block diagram of a bus structure with attached energy harvesting devices.

FIG. 3 depicts a block diagram of a bus structure with attached energy storing devices.

FIG. 4 depicts a block diagram of a bus structure with attached energy consuming devices.

FIG. 5 depicts a block diagram of a bus structure with attached sensor devices.

FIG. 6 depicts a block diagram of a bus structure with a control device.

FIG. 7A depicts a block diagram of a multiline bus structure with shared power and data lines.

FIG. 7B depicts a block diagram of a multiline bus structure with separate power and data lines.

FIG. 8A depicts a block diagram a conductive bus coupling structure.

FIG. 8B depicts a block diagram of a capacitive bus coupling structure.

FIG. 8C depicts a block diagram of an inductive bus coupling structure.

FIG. 9A depicts a block diagram of a bus receiver interface.

FIG. 9B depicts a block diagram of a bus transmitter interface.

FIG. 9C depicts a block diagram of a bus transceiver interface.

FIG. 10 depicts a block diagram of a bus power coupler.

### DETAILED DESCRIPTION

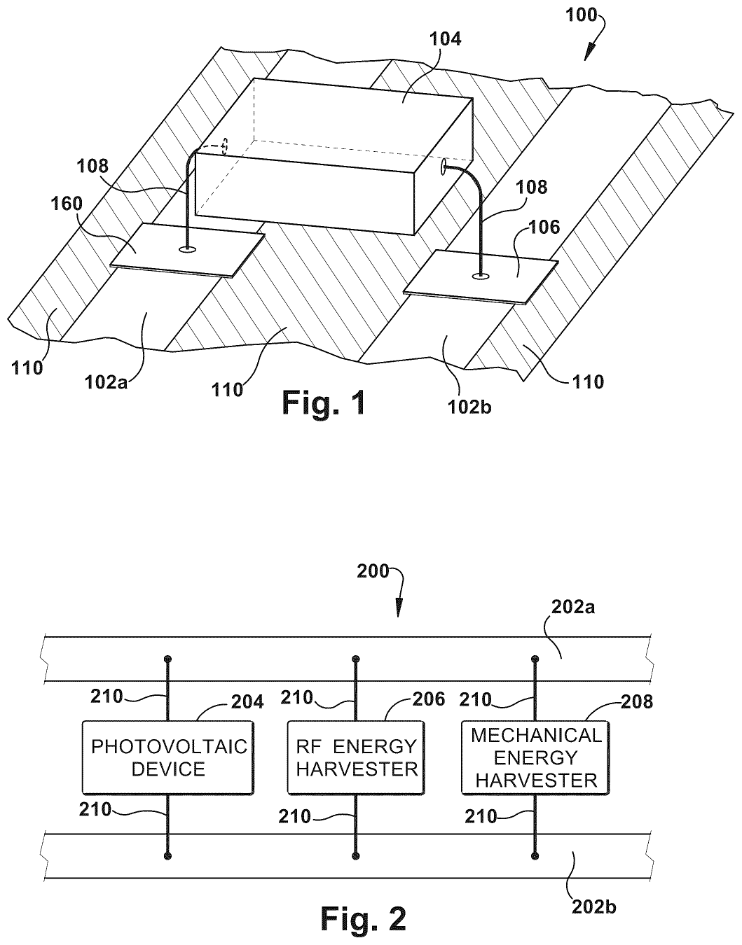

The systems and methods disclosed herein are described in detail by way of examples and with reference to FIGS. 1 to 10. It will be appreciated that modifications to disclosed and described examples, arrangements, configurations, components, elements, apparatuses, devices methods, systems, etc. can suitably be made and may be desired for a specific application. In this disclosure, any identification of specific techniques, arrangements, etc. are either related to a specific example presented or are merely a general description of such a technique, arrangement, etc. Identifications of specific details or examples are not intended to be, and should not be, construed as mandatory or limiting unless specifically designated as such.

The systems and methods disclosed herein describe bus structures suitable for strap attachment devices. The use of a common bus structure having the ability to receive multiple different types of devices, each of which is connectable to the bus via similar straps, allows for rapid development of different applications. Certain aspects detailing the strap attachment of devices, such as chips, are disclosed in U.S. Pat. Nos. 6,606,247 and 7,292,148 which are incorporated herein by reference.

FIG. 1 is an illustration of an exemplary embodiment of a bus structure 100 for the strap attachment of devices. The bus structure 100 includes a first bus conductor 102a, or bus rail, and a second bus conductor 102b (collectively bus 102), although any suitable number of bus conductors 102 can be used as described below. A device 104 is connected to the bus 102 via straps 106, 160. Any suitable electrical connection 108 between the device 104 and the straps 106, 160 can be used, for example a wire as shown or surface mounting the device 104 to the straps 106, 160 as would be understood in the art. Advantageously, the straps 106, 160 can facilitate attachment of devices 104 to the bus 102 using high speed roll to roll processing devices. Exemplary devices 104 can include energy harvesting devices, energy storage devices, energy consuming devices, sensor devices, control devices, or other suitable types of devices for example as described below in greater detail.

The bus 102 can be formed on a non-conductive flexible substrate 110, for example a plastic such as polyethylene terephthalate (“PET”), a paper such as a treated or coated paper, or other suitable flexible substrates commonly used in roll-to-roll technologies. The substrate 110 can include an adhesive backing for attachment to items. In certain embodiments, the bus 102 can be formed using a conductive ink that is printed on the substrate 110. In other embodiments, the bus 102 can be formed from a suitable metal foil such as aluminum or a copper cladded aluminum substrate 110. In certain embodiments, the metal foil can be die cut, etched, or laser cut/etched, or a combination thereof. In still other embodiments, the bus 102 can be formed by selective vacuum deposition of a metal onto a suitable substrate 110. According to one aspect of the invention, the substrate is derived from a web made of thin, flexible, and long material. The web materials are then stored or transported as rolls for and between roll-to-roll processing stages. The materials may include paper, foil, plastic films, textiles, metals, and even nanomaterials.

In certain aspects of the invention, the non-conductive flexible substrate 110 and bus 102 are manufactured together and packaged into a roll suitable for roll-to-roll processing. The roll is later fed into a roll-to-roll processing device to attach multiple devices 104 to a length of the bus 102 in accordance with the desired application to be accomplished by the devices 104.

FIG. 2, an illustration of an exemplary bus structure 200 with attached energy harvesting devices 204, 206, and 208. The bus structure 200 includes a first bus conductor 202a and a second bus conductor 202b (collectively bus 202). An example energy harvesting device 204, 206, and/or 208 is a photovoltaic device 204, or solar cell, configured to generate power from ambient light incident on the photovoltaic device 204. Another example energy harvesting device 204, 206, and/or 208 is a radio frequency energy harvester 206 configured to extract energy from ambient or directed radio waves received on an associated antenna. Yet another example energy harvesting device 204, 206, and/or 208 is a mechanical energy harvester 208, such as a piezoelectric element and associated electronics/electrical components, that captures energy released when the piezoelectric element is flexed. The energy harvesting devices 204, 206, and/or 208 extract energy from the environment and deliver power to the bus 202 for use by other devices.

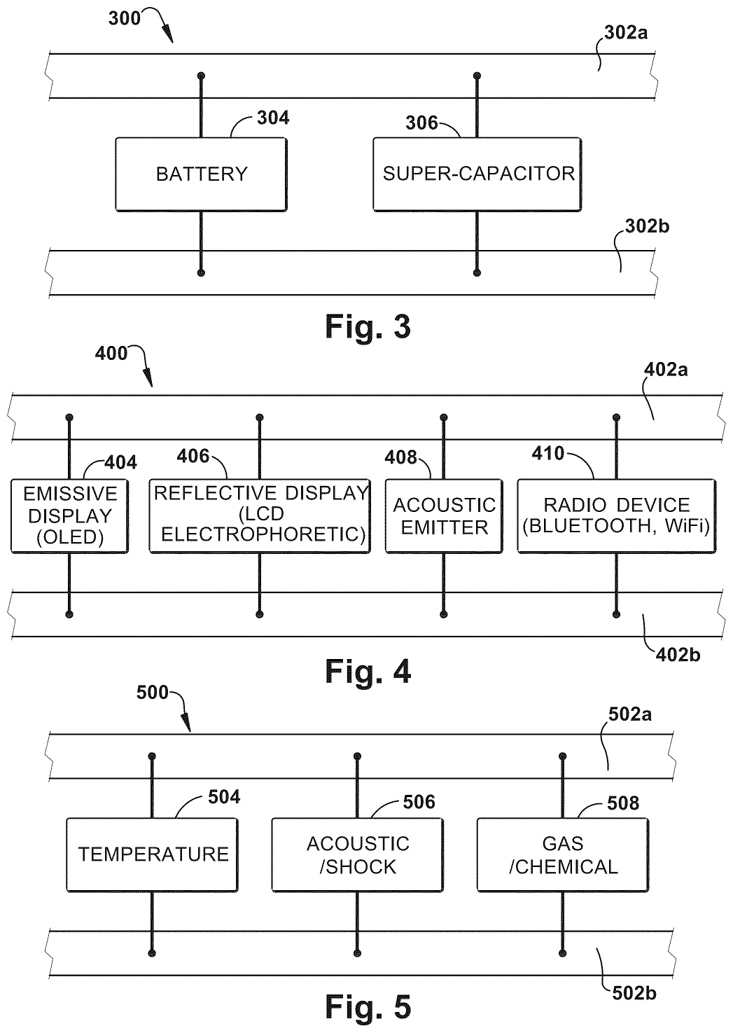

FIG. 3 is an illustration of an exemplary bus structure 300 with attached energy storing devices 304 and 306. The bus structure 300 includes a first bus conductor 302a and a second bus conductor 302b (collectively bus 302). An example energy storing device 304 and 306 is a battery device 304 that can provide power to other devices on the bus. In related embodiments, the battery device 304 can be a rechargeable battery that can be charged when power is available on the bus 302. Another example energy storing device 304 and 306 is a capacitive device 304, for example a supercapacitor, that can store energy from the bus 302 when power is available and provide power to the bus 302 when power is needed by other devices. For example, if a bus 302 includes photovoltaic device, then an energy storing device 304 and/or 306 can store power from the bus 302 when there is light available for the photovoltaic device to generate power, and provide power to the bus 302 when it is dark and the photovoltaic device does not generate power.

FIG. 4 is an illustration of an exemplary bus structure 400 with attached energy consuming devices 404, 406, 408, and/or 410. The bus structure 400 includes a first bus conductor 402a and a second bus conductor 402b (collectively bus 402). An exemplary energy consuming device 404, 406, 408, and/or 410 is an emissive display device 404, such as an organic light emitting diode display. Another example energy consuming device 404, 406, 408, and/or 410 is a reflective display device 406, such as a liquid crystal display or an e-ink display. Yet another example energy consuming device 404, 406, 408, and/or 410 is an acoustic emitting device 408, for example a piezoelectric speaker element. Yet another example energy consuming device 404, 406, 408, and/or 410 is a radio device 410, such as a Bluetooth low energy beacon, or a WIFI device among other suitable types of devices that emit radio frequency signals. The energy consuming devices 404, 406, 408, and/or 410 can transfer power, or power and data, from the bus 402. The data can include commands and associated data for changing the information displayed on a display device 404, 406, emitting an acoustic signal from an acoustic emitter device 408, or transmitting or reflecting a radio signal from a radio device 410.

FIG. 5 is an illustration of an exemplary bus structure 500 with attached sensor devices 504, 506, and/or 508. The bus structure 500 includes a first bus conductor 502a and a second bus conductor 502b (collectively bus 502). The sensor devices 504, 506, and/or 508 can be powered by the bus and can send sensor data via the bus, for example in response to being polled by another device or in response to a triggering event. An example sensor device 504, 506, and/or 508 is a temperature sensor 504, where the sensed temperature can be delivered as sensor data to the bus either as a specific data point, a time-varying waveform, or a computed value such as an integral of the temperature values over a period of time. Another example sensor device 504, 506, and/or 508 is an acoustic energy, accelerometer, Hall effect sensor, or shock sensor 506, or the like, that can send sensor data such as a time-varying waveform, an exceeded threshold, or a discrete event such as a change of state of an element that breaks when sufficiently stressed. Yet another example sensor device 504, 506, and/or 508 is a gas or chemical sensor 508 configured to sense one or more chemicals, for example a carbon monoxide sensor, a smoke sensor, a water sensor, a PH acid-base detector, or an explosive analyte detector, or the like.

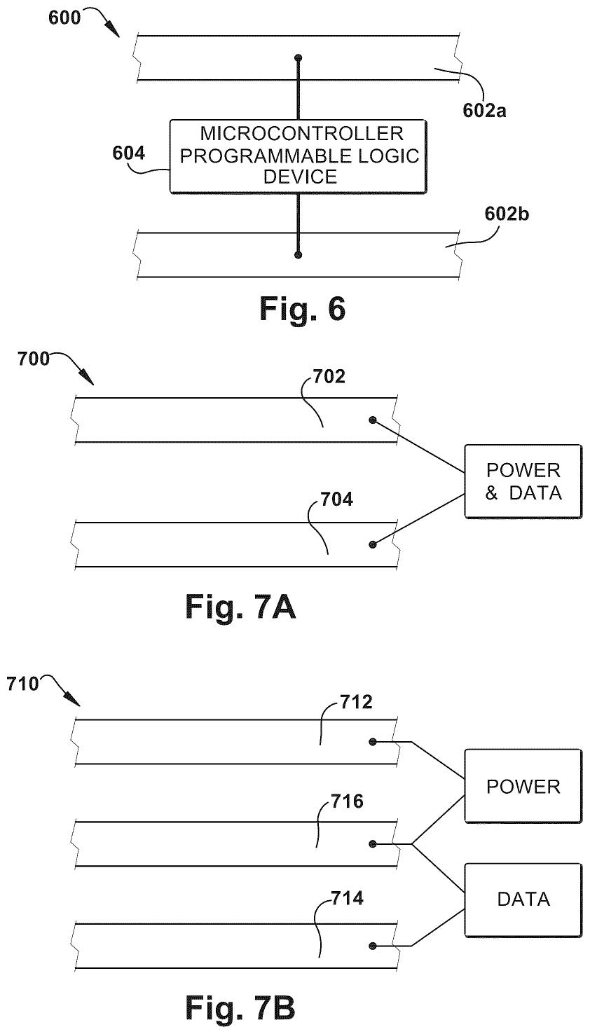

FIG. 6 is an illustration of an exemplary bus structure 600 with an attached control device 604. The bus structure 600 includes a first bus conductor 602a and a second bus conductor 602b (collectively bus 602). An example control device 604 can be a suitable microcontroller, a programmable logic device, or any other suitable processor. The control device 604 can be powered by the bus, for example from an energy harvesting device or an energy storing device. The control device 604 can send to, and receive data from, other devices via the bus 602. The control device 604 can send data to devices, for example text or images to be displayed on a display device. The control device 604 can send commands to devices, for example polling a sensor device for sensor data. The control device 604 can receive data from devices, for example sensor data from sensor devices.

FIG. 7A is an illustration of an exemplary multiline bus structure 700 with shared power and data lines. The multiline bus structure 700 includes a first shared bus line 702 and a second shared bus line 704. Both the power and the data can be carried on the first shared bus line 702 and a second shared bus line 704. For example, the power can be carried as direct current (DC) power, for example 5 Volts DC. In another example, the power can be carried as alternating current (AC) power, for example 50 Hertz (Hz), 60Hz, 400 Hz, or higher AC power. In these embodiments, the data can be transmitted as a modulated signal, for example a modulated signal having a 25 MHz carrier signal.

FIG. 7B is an illustration of an exemplary multiline bus structure 710 with separate power and data lines. The multiline bus structure 710 includes a power line 712, a data line 714, and a common line 716 also called a return line. Power can be transmitted on the power 712 with the common line acting as neutral or ground. Data can be carried using the data line 714 and the common line 716 either in a balanced or unbalanced mode as would be understood in the art. As would be understood in the art, any suitable or desired number of power lines 712, data lines 714, and common lines 716 can be used according to the application. Further, the power lines 712, data lines 714, and common lines 716 can be provided in any orientation with respect to each other.

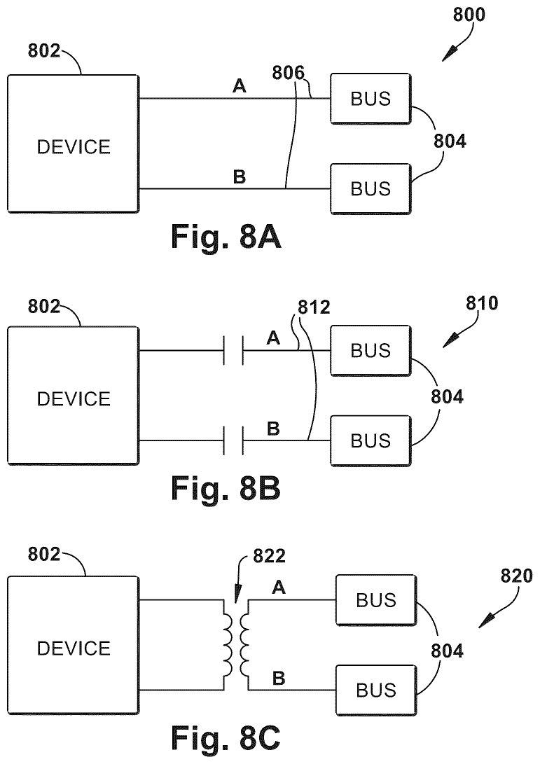

FIG. 8A is an illustration of an exemplary embodiment of a conductive bus coupling structure 800. A device 802 is connected to the bus 804 using straps configured as ohmic, or conductive coupling elements 806. Exemplary coupling devices 804 include energy harvesting devices, energy storage devices, energy consuming devices, sensor devices, control devices, or other suitable types of devices as discussed above. Exemplary conductive coupling elements 806 can include conductive adhesive or strips, welding or soldering, crimping or other mechanical connectors, or electrochemical connections for example growing a conductor between the conductive pads on the device 802 and the bus 804. Conductive coupling elements 806 allow both DC and AC power as well as data to be passed between the device 802 and the bus 804.

FIG. 8B is an illustration of an exemplary embodiment of a capacitive bus coupling structure 810. A device 802 is connected to the bus 804 using straps configured as capacitive coupling elements 812. Exemplary capacitive elements 812 can include non-conductive adhesives such as a pressure sensitive adhesive that has a relatively high dielectric constant and which improves signal and power transfer due to the high capacitance. Capacitive coupling elements 812 block DC power but allow AC power and data signals to be passed between the device 802 and the bus 804.

FIG. 8C is an illustration of an exemplary embodiment of an inductive bus coupling structure 820. A device 802 is connected to the bus 804 using straps configured as inductive coupling elements 822. Exemplary inductive coupling elements 822 can include coils that are electromagnetically coupled to one another. The coils are positioned in close proximity to one another such that magnetic flux generated in one coil induces a current in the adjacent coil. A high permeability material can be used to increase the coupling of magnetic flux between the coils. Inductive coupling elements 822 block DC power but allow AC power, and in some instances data signals, to be passed between the device 802 and the bus 804.

In various embodiments, more than one coupling method or coupling structure 800, 810, 820 can be used on a bus 804. For example, an energy harvesting device can use a conductive coupling element 806 on the bus 804 while a sensor device on the same bus 804 can use a capacitive coupling element 812. However, using capacitive coupling elements 812 facilitates use in high-speed roll to roll processing. Devices 802 using capacitive coupling elements 812 include circuit structures for transferring energy or data from the bus 804 or onto the bus 804.

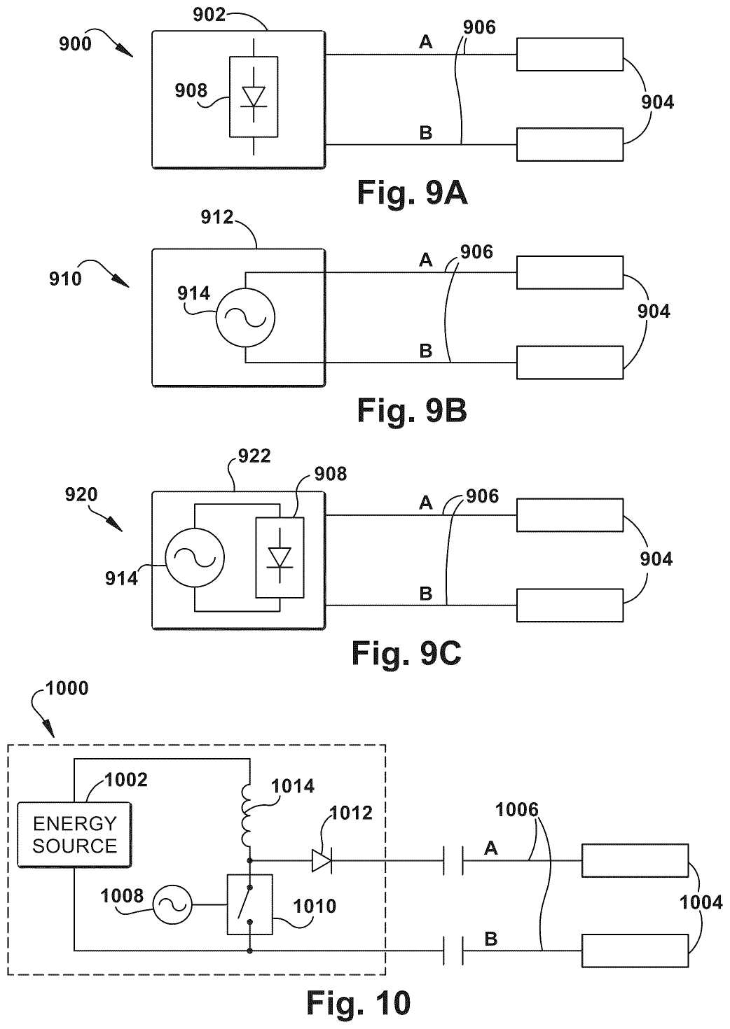

FIG. 9A is an illustration of an embodiment of an exemplary bus receiver interface 900. A device 902 is coupled to a bus 904 by straps configured as non-conductive coupling elements 906 via capacitance, mutual inductance, or a combination of capacitance and mutual inductance. The device 902 includes one or more rectifiers 908 or detectors configured to convert a coupled AC signal to DC power for powering circuity. Data can be detected and demodulated from the coupled signal.

FIG. 9B is an illustration of an exemplary embodiment of a bus transmitter interface 910. A device 912 is coupled to a bus 904 by straps configured as non-conductive coupling elements 906. The device 912 includes one or more oscillators 914 configured to put power or data onto the bus 904. In some embodiments, the device can put power or data onto the bus 904 in response to commands received from a controller device as described above, or continuously depending upon how the device 902 is configured to operate. The frequencies used by the oscillators 914 can depend upon the use or function of those frequencies on the bus 904. For example, power may be a 10 MHz AC signal on the bus 904, while data may be a pulse width modulated, amplitude modulated, or frequency modulated signal using a 25 MHz carrier.

FIG. 9C is an illustration of an embodiment of an exemplary bus transceiver interface 920 is presented. The device 922 is coupled to a bus 904 by straps configured as non-conductive coupling elements 906. The device 922 includes one or more rectifiers 908 or detectors configured to receive power and signals from the bus 904, and one or more oscillators 914 to transfer power or signals onto the bus 904.

In some embodiments, the rectifiers 908 and oscillators 914 includes suitable electronic components, such as transistors, resistors, capacitor, inductors, integrated circuits, and appropriate logic, that are combined into a suitable circuit as would be understood in the art.

FIG. 10 is an exemplary bus power coupler 1000. The bus power coupler 1000 includes an energy source 1002, such as an energy storage device or energy harvesting device. Power delivered to the bus 1004 from the energy source 1002 is controlled by a switch 1010 that is driven by suitable control 1008 such as an oscillator. When the switch 1010 is closed by a driver signal from the control 1008, power from the energy source 1002 is stored in a magnetic field of a suitable inductor 1014. When the switch 1010 is opened by the control 1008, the magnetic field in the inductor 1014 collapses causing a pulse of energy to pass through a diode 1012, or another suitable rectifying device, to the bus 1004 across straps configured as capacitive coupling elements 1006. The switch 1010 is then closed by the control 1008 and a new magnetic field is generated in the inductor 1014 by the flow of current from the energy source 1002 through the inductor 1014.

The values disclosed herein are not to be understood as being strictly limited to the exact numerical values recited. Instead, unless otherwise specified, each such dimension is intended to mean both the recited value and a functionally equivalent range surrounding that value. It should be understood that every maximum numerical limitation given throughout this specification includes every lower numerical limitation, as if such lower numerical limitations were expressly written herein. Every minimum numerical limitation given throughout this specification will include every higher numerical limitation, as if such higher numerical limitations were expressly written herein. Every numerical range given throughout this specification will include every narrower numerical range that falls within such broader numerical range, as if such narrower numerical ranges were all expressly written herein.

Every document cited herein, including any cross-referenced or related patent or application, is hereby incorporated herein by reference in its entirety unless expressly excluded or otherwise limited. The citation of any document is not an admission that it is prior art with respect to any invention disclosed or claimed herein or that it alone, or in any combination with any other reference or references, teaches, suggests, or discloses any such invention. Further, to the extent that any meaning or definition of a term in this document conflicts with any meaning or definition of the same term in a document incorporated by reference, the meaning or definition assigned to that term in the document shall govern.

The foregoing description of embodiments and examples has been presented for purposes of description. It is not intended to be exhaustive or limiting to the forms described. Numerous modifications are possible in light of the above teachings. Some of those modifications have been discussed and others will be understood by those skilled in the art. The embodiments were chosen and described for illustration of various embodiments. The scope is, of course, not limited to the examples or embodiments set forth herein, but can be employed in any number of applications and equivalent articles by those of ordinary skill in the art. Rather it is hereby intended the scope be defined by the claims appended hereto.

1. A bus, comprising:
a substrate that is flexible and non-conductive and configured for roll-to-roll processing;
a plurality of bus conductors disposed on the substrate and configured to: receive at least one device, and
transfer one or more of power or data signals to the at least one device; and
at least one strap configured to couple a respective bus conductor of the plurality of bus conductors to a respective contact of the at least one device.

2. The bus of claim 1, wherein the at least one device is an energy harvester device selected from the group consisting of:
a photovoltaic cell,
a radio frequency energy harvester, and
a mechanical energy harvester.

3. The bus of claim 1, wherein the at least one device is an energy storage device that includes one or more of:
a battery,
a rechargeable battery,
a capacitor, or
a supercapacitor.

4. The bus of claim 1, wherein the at least one device is an energy consuming device selected from the group consisting of:
an emissive display,
a reflective display,
an acoustic emitter, and
a radio signal device.

5. The bus of claim 1, wherein the at least one device is a sensor device selected from the group consisting of:
a temperature sensor,
an acoustic energy sensor,
an accelerometer,
a shock sensor,
a gas sensor,
a smoke sensor,
a carbon monoxide sensor,
a water sensor,
a PH sensor,
a Hall effect sensor, and
a chemical sensor.

6. The bus of claim 1, wherein the at least one device is a control device that includes one or more of:
a processor,
a programmable logic device, or
a microcontroller.

7. The bus of claim 1, wherein the substrate includes a material selected from the group consisting of plastic, polyethylene terephthalate, treated paper, and coated paper.

8. The bus of claim 1, wherein each conductor is selected from the group consisting of a conductive ink printed onto the substrate, a metal foil secured on the substrate, an aluminum metal foil secured on the substrate, a copper clad metal foil secured on the substrate, a die cut metal foil secured on the substrate, a laser etched metal foil secured on the substrate, and a metal vacuum deposited onto the substrate.

9. The bus of claim 1, wherein the substrate and the plurality of bus conductors are configured to be stored in a roll without devices and receive a plurality of the at least one device that are attached to two or more of the plurality of bus conductors via roll-to-roll processing.

10. The bus of claim 1, wherein the plurality of bus conductors comprise exactly two bus conductors configured to conduct both power and data signals.

11. The bus of claim 1, wherein the plurality of bus conductors comprises at least one bus conductor configured to conduct only power and at least one bus conductor configured to conduct only data signals.

12. The bus of claim 1, wherein the at least one device is conductively coupled by respective ones of the at least one strap to at least two bus conductors of the plurality of bus conductors.

13. The bus of claim 1, wherein the at least one device is capacitively coupled by respective ones of the at least one strap to at least two bus conductors of the plurality of bus conductors via a pressure sensitive adhesive.

14. The bus of claim 1, wherein the at least one device is inductively or capacitively coupled by respective ones of the at least one strap to at least two bus conductors of the plurality of bus conductors.

15. The bus of claim 14, wherein the at least one device includes a rectifier circuit configured to convert an alternating current signal from one or more of the plurality of bus conductors into direct current.

16. The bus of claim 14, wherein the at least one device includes a detector circuit configured to demodulate data from a data signal received from one or more of the plurality of bus conductors.

17. The bus of claim 14, wherein the at least one device includes an oscillator circuit configured to modulate data or power that is coupled onto one or more of the plurality of bus conductors.

18. A bus for roll-to-roll processing, comprising:
a flexible non-conductive substrate configured for roll-to-roll processing; and
a plurality of flexible bus conductors disposed on the substrate, configured to:
transfer one or more of power or data signals, and
receive a plurality of devices with straps that are configured to be capacitively coupled to at least two bus conductors using a pressure sensitive adhesive.

19. The bus for roll-to-roll processing of claim 18, further comprising:
a plurality of devices with straps, each device attached to respective bus conductors with pressure sensitive adhesive via roll-to-roll processing, and each selected from the group consisting of an energy harvester device, an energy storage device, an energy consuming device, a sensor device, and a control device.

20. A method, comprising:
receiving, in a roll-to-roll processing device, a roll of flexible non-conductive substrate that includes, disposed on the substrate, a plurality of flexible bus conductors configured to receive a plurality of devices with straps and transfer one or more of power or data signals between the plurality of devices; and
attaching, in a roll to roll processing device and using a pressure sensitive adhesive, each of the plurality of devices with straps to at least two of the plurality of flexible bus conductors,
wherein the pressure sensitive adhesive capacitively couples each device to the at least two of the plurality of flexible bus conductors.
